(19) United States
(12) Patent Application Publication
(10) Pub. No.: US 2012/0087108 A1
(43) Pub. Date: Apr. 12, 2012

(54) LED Apparatus

(75) Inventors: Wei-Chih Ke, Hsin-Chu (TW); Chih-Lin Wang, Hsin-Chu (TW); Yu-Hsien Liu, Hsin-Chu (TW); Ruei-Teng Lin, Hsin-Chu (TW)

(73) Assignee: AU OPTRONICS CORPORATION, Hsin-Chu (TW)

(21) Appl. No.: 13/271,408

(22) Filed: Oct. 12, 2011

(30) Foreign Application Priority Data
Oct. 12, 2010 (TW) 099134705
Oct. 7, 2011 (TW) 100136843

(51) Int. Cl. G09F 13/04; H01L 33/08

(52) U.S. Cl. 362/97.1; 257/89; 257/E33.012

(57) ABSTRACT

An LED apparatus is disclosed. The LED apparatus includes a substrate, a cup structure, and a dividing structure. The dividing structure divides a containing space formed by the cup structure into a first region and a second region. A first blue-light chip and a first package colloidal are disposed in the first region and a second blue-light chip and a second package colloidal are disposed in the second region. A green-light phosphor is mixed in the second package colloidal to completely convert a monochromatic emission spectrum of a second blue-light band of the second blue-light chip into a monochromatic emission spectrum of a green-light band. The green-light phosphor is selected from one of silicate, oxynitride, lutetium aluminum oxide, and calcium scandium oxide.

### BACKGROUND OF THE INVENTION

1. Field of the Invention

The invention relates to a light-emitting diode (LED), in particular, to a LED apparatus applied in a liquid crystal display using a blue light chip and a phosphor to form a single-color light source of green light or red light to reduce the characteristic difference between the different color light chips of the conventional LED apparatus to enhance the overall efficiency of the LED apparatus.

2. Description of the Prior Art

In recent years, with the continuous development of the display technology, it is no doubt that the liquid crystal display (LCD) is the mainstream of the flat panel display technology. Among all kinds of LCD, the color sequential LCD (CS-LCD) can increase the gamut and saturation of the system, lower the material cost, and even largely enhance the electro-optical conversion efficiency of the display panel, therefore, the CS-LCD can meet the specifications of wide gamut, high resolution, and low power consumption for the new generation flat panel display technology.

Because the color filter is not needed in the CS-LCD, the pixels of the liquid crystal module of the CS-LCD need not to be divided into sub-pixels. Taking the direct-type backlight module shown in FIG. 1 for example, the red (R) light source 10, the green (G) light source 12, and the blue (B) light source 14 in the LED backlight module 1 are switched according to a time sequence, and the liquid crystal pixel penetrating rate is synchronously controlled in display time of various color lights to adjust the relative light intensity of the primary colors, and then the vision system performs integration on light stimulation to form the colors of the direct-type backlight module. Because the lights emitted from the LED have the spectrum of narrow full width at half maximum, the color having high color saturation can be shown and the system gamut can be also enlarged. Therefore, the CS-LCD has better color saturation performance than conventional LCD using the color filter.

Please refer to FIG. 2. FIG. 2 shows another LED design of the backlight module of the conventional CS-LCD. As shown in FIG. 2, the LED 20 of the CS-LCD uses the red-light LED chip 200, the green-light LED chip 202, the blue-light LED chip 204 disposed in the containing space S enclosed by the cup structure 21 to emit the red light, the green light, and the blue light in order respectively at a specific time. And then the red light, the green light, and the blue light are mixed. Since the switching rate of the color sequence is faster than the perceiving frequency of human eyes, human brain will superpose the screen effects to feel the full-color screen due to the vision persistence effect.

In general, the CS-LCD has many advantages as follows. (1) Since the CS-LCD needs not to use the color filter, the cost can be lowered and the overall efficiency can be increased. (2) Since the complicated design of RGB sub-pixels is unnecessary, the yield of the TFT array substrate can be increased, and the complexity of the control circuit can be simplified, and the power consumption can be also reduced. (3) The aperture ratio between the pixels is increased, so that the space of the panel pixel is enlarged, and the panel pixel will have high resolution. (4) The CS-LCD can show colors having high color saturation and the gamut of the system can be effectively enlarged.

However, the LED 20 of the CS-LCD must have the red-light LED chip 200, the green-light LED chip 202, and the blue-light LED chip 204 at the same time. Since these three LED chips of different primary colors have different characteristics such as photoelectric characteristic or lifetime respectively, and the efficiency of the green-light LED chip 202 is poor, and the red-light LED chip 200 is too sensitive to temperature, the phenomenon of thermal decay and color distortion will be easily caused, the overall efficiency and lifetime of the CS-LCD will be seriously affected.

### SUMMARY OF THE INVENTION

Therefore, a scope of the invention is to provide a LED apparatus applied in a liquid crystal display (LCD) to solve the above-mentioned problems in the prior arts.

In an embodiment of the invention, a LCD apparatus includes a liquid crystal panel and a backlight module, and the backlight module is disposed corresponding to the liquid crystal panel. The backlight module includes a frame and a LED light bar, and the LED light bar is disposed in the frame. The LED light bar includes a circuit board and a LED apparatus, and the LED apparatus is disposed on the circuit board.

The LED apparatus includes a substrate, a cup structure, and a dividing structure. The dividing structure divides a containing space formed by the cup structure into a first region and a second region. A first blue-light chip and a first package colloidal are disposed in the first region and a second blue-light chip and a second package colloidal are disposed in the second region. A green-light phosphor is mixed in the second package colloidal to completely convert a monochromatic emission spectrum of a second blue-light band of the second blue-light chip into a monochromatic emission spectrum of a green-light band. The green-light phosphor is selected from one of silicate, oxynitride, lutetium aluminum oxide, and calcium scandium oxide.

In an embodiment, the silicate is selected as the green-light phosphor, and the weight ratio between the green-light phosphor and the second package colloidal ranges between 80% and 160%. In fact, the silicate can include (Ca,Sr,Ba)₂SiO₄:Eu.

In an embodiment, the oxynitride is selected as the green-light phosphor, and the weight ratio between the green-light phosphor and the second package colloidal ranges between 90% and 180%. In fact, the oxynitride can include β-SiAlON:Eu.

In an embodiment, the lutetium aluminum oxide is selected as the green-light phosphor, and the weight ratio between the green-light phosphor and the second package colloidal ranges between 80% and 160%. In fact, the lutetium aluminum oxide can include Lu₃Al₅O₁₂:Ce.

In an embodiment, the calcium scandium oxide is selected as the green-light phosphor, and the weight ratio between the green-light phosphor and the second package colloidal ranges between 90% and 180%. In fact, the calcium scandium oxide can include CaSc₂O₄:Ce.

In an embodiment, a first red-light chip is further disposed in the first region, the first red-light chip has a monochromatic emission spectrum of a first red-light band, and the first package colloidal covers and packages the first blue-light chip and the first red-light chip.

In an embodiment, the dividing structure further divides the containing space to form a third region. In fact, a second red-light chip and a third package colloidal can be disposed in the third region; the second red-light chip has a monochromatic emission spectrum of a second red-light band, and the third package colloidal covers and packages the second red-light chip.

In addition, a third blue-light chip and a fourth package colloidal can be disposed in the third region, the third blue-light chip has a monochromatic emission spectrum of a third blue-light band, and the fourth package colloidal covers and packages the third blue-light chip, a red-light phosphor is mixed in the fourth package colloidal, the red-light phosphor completely converts the monochromatic emission spectrum of the third blue-light band into a monochromatic emission spectrum of a red-light band; wherein nitride is selected as the red-light phosphor.

In an embodiment, the weight ratio between the red-light phosphor and the third package colloidal ranges between 24% and 120%. In fact, the nitride can include (Ca,Sr)AlSiN₃:Eu or (Ca,Sr,Ba)₂Si₅N₈:Eu.

In another embodiment, the LED apparatus includes a substrate, a cup structure, and a dividing structure. The dividing structure divides a containing space formed by the cup structure into a first region and a second region. A first blue-light chip and a first package colloidal are disposed in the first region and a second blue-light chip and a second package colloidal are disposed in the second region. A phosphor is mixed in the second package colloidal to convert a monochromatic emission spectrum of a second blue-light band of the second blue-light chip into a white-light emission spectrum.

In an embodiment, the phosphor is selected from one of a yellow-light phosphor, a yellow-light and red-light phosphor, and a green-light and red-light phosphor.

In an embodiment, the dividing structure further divides the containing space to form a third region, and the third region includes a third blue-light chip having a monochromatic emission spectrum of a third blue-light band and a third package colloidal covering and packaging the third blue-light chip.

In an embodiment, a red-light or green-light phosphor is mixed in the third package colloidal, and the red-light phosphor completely converts the monochromatic emission spectrum of the third blue-light band into a monochromatic emission spectrum of a red-light band or the green-light phosphor completely converts the monochromatic emission spectrum of the third blue-light band into a monochromatic emission spectrum of a green-light band.

In an embodiment, a red-light phosphor is mixed in the third package colloidal and a green-light phosphor is mixed in the first package colloidal. The red-light phosphor completely converts the monochromatic emission spectrum of the third blue-light band into a monochromatic emission spectrum of a red-light band, and the green-light phosphor completely converts the monochromatic emission spectrum of the first blue-light band into a monochromatic emission spectrum of a green-light band.

In another embodiment, a field sequential display includes a display module and a back-light module. The display module has a color filter of single color, and the back-light module has a plurality of LED apparatuses. The LED apparatus includes a substrate, a cup structure, and a dividing structure. The cup structure is disposed on the substrate and encloses a containing space. The dividing structure is disposed in the containing space and divides the containing space into a plurality of regions. A first region of the plurality of regions forms a white light, and the first region corresponds to the color filter of single color.

In an embodiment, the color partially disposes on the color filter of singe color.

In an embodiment, the color filter of single color is a green color filter, and a second region and a third region of the plurality of regions not corresponding to the green color filter form a blue-light and a red-light respectively.

In an embodiment, the color filter of single color light is a red color filter, and a second region and a third region of the plurality of regions not corresponding to the red color filter form a blue-light and a green-light respectively.

In an embodiment, the color filter of single color light is a blue color filter, and a second region and a third region of the plurality of regions not corresponding to the blue color filter form a red-light and a green-light respectively.

Compared to the prior arts, the LED apparatus in the LCD of the invention uses the blue-light chip and the phosphor to form the green-light monochromatic light source or red-light monochromatic light source to effectively reduce the characteristic differences among the three different color light chips in the conventional LED apparatus. The green-light monochromatic light source formed by the blue-light chip and the phosphor has much higher efficiency than the conventional green-light chip, and the red-light monochromatic light source formed by the blue-light chip and the phosphor has better thermal stability than the conventional red-light chip, therefore, the overall efficiency of the LED apparatus in the invention is obviously better than that of the conventional LED apparatus having three different color light chips. In addition, the invention also discloses the LED apparatus suitable used in the hybrid field sequential color display, it uses a single blue-light chip cooperated with a phosphor to form a white-light source, and cooperates with a red-light filter, a blue-light filter, or a green-light filter to convert a part of the white light into a red light, a blue light, or a green light, it is not necessary to drive chip chips at the same time to mix the red light, the blue light, and the green light into the white light, therefore, the efficiency of the LED apparatus can be largely increased, and the color break-up (CBU) phenomenon can be reduced by the generated four-color image to improve the quality of the displayed image. Moreover, the LED apparatus of the invention also has advantages of stabler white light, higher productivity, and lower cost, so that the competitiveness of the hybrid field sequential color display having the LED apparatus can be effectively enhanced.

The advantage and spirit of the invention may be understood by the following detailed descriptions together with the appended drawings.

### BRIEF DESCRIPTION OF THE APPENDED DRAWINGS

FIG. 1 illustrates a schematic diagram of the conventional CS-LCD switching the red light source, the green light source, and the blue light source in the LED backlight module according to a time sequence.

FIG. 2 shows a LED design of the backlight module of the conventional CS-LCD.

FIG. 3 illustrates a cross-sectional view of the LED apparatus in an embodiment of the invention.

FIG. 4 illustrates a cross-sectional view of the LED apparatus in another embodiment of the invention.

FIG. 5 illustrates a cross-sectional view of the LED apparatus in another embodiment of the invention.

FIG. 6 illustrates a cross-sectional view of the LED apparatus cooperating with a green-light filter.

FIG. 7 illustrates a cross-sectional view of the LED apparatus cooperating with a red-light filter.

FIG. 8 illustrates a cross-sectional view of the LED apparatus cooperating with a blue-light filter.

### DETAILED DESCRIPTION OF THE INVENTION

The invention discloses a LED apparatus applied in a liquid crystal display (LCD). In view of the poor efficiency of the green-light LED chip of the LED apparatus of the prior art, and the red-light LED chip of the LED apparatus of the prior art is too sensitive to temperature, the phenomenon of thermal decay and color distortion is easily caused in prior art, the LED apparatus of the invention uses the blue-light LED chip and the phosphor to form the green-light or red-light monochromatic light source to reduce the characteristic difference between the different color light LED chips, so that the overall efficiency of the LCD of the invention can be enhanced.

A preferred embodiment of the invention is a LED apparatus applied in a LCD. In this embodiment, the LCD is a color sequential LCD (CS-LCD). The LCD includes a liquid crystal panel and a backlight module, and the backlight module is disposed corresponding to the liquid crystal panel. The backlight module includes a frame and a LED light bar, and the LED light bar is disposed in the frame. The LED light bar includes a circuit board and a LED apparatus, and the LED apparatus is disposed on the circuit board. Then, the LED apparatus of the above-mentioned backlight module will be discussed in detail as follows.

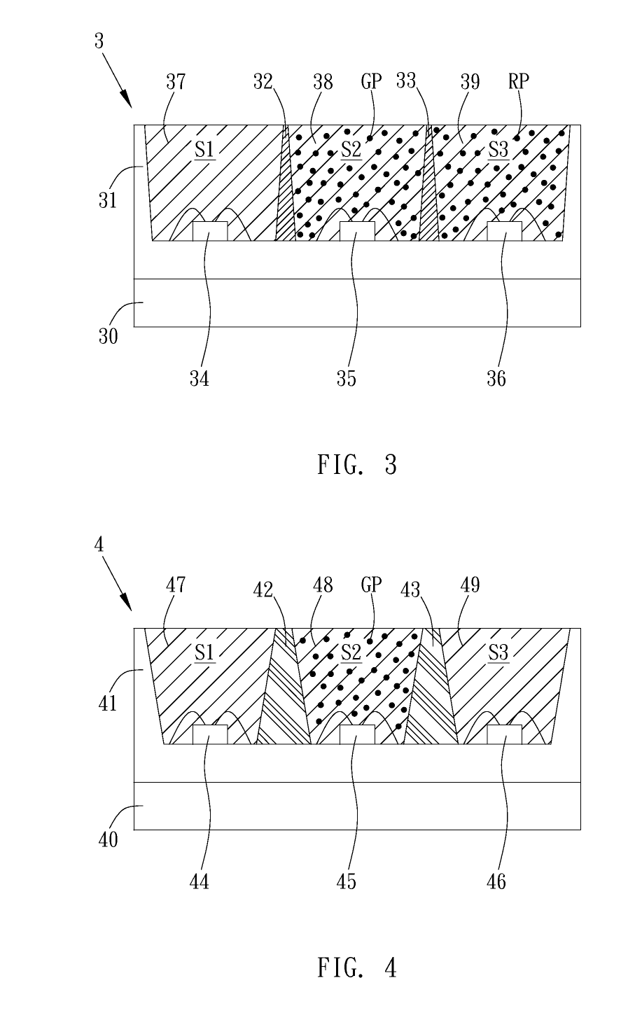

Please refer to FIG. 3. FIG. 3 illustrates a cross-sectional view of the LED apparatus in this embodiment of the invention. As shown in FIG. 3, the LED apparatus 3 includes a substrate 30, a cup structure 31, a first dividing structure 32, a second dividing structure 33, a first blue-light chip 34, a second blue-light chip 35, a third blue-light chip 36, a first package colloidal 37, a second package colloidal 38, a fourth package colloidal 39, a green-light phosphor GP, and a red-light phosphor RP.

In this embodiment, the cup structure 31 is disposed on the substrate 30 and encloses a containing space. The first dividing structure 32 and the second dividing structure 33 are disposed in the containing space, and the first dividing structure 32 and the second dividing structure 33 divide the containing space into a first region S1, a second region S2, and a third region S3. In a preferred embodiment, the first dividing structure 32 and the second dividing structure 33 is thinner than the sidewall of the cup structure 31, the first region S1, the second region S2, and the third region S3 can be closer to obtain better light-mixing effect. Wherein, the first blue-light chip 34 and the first package colloidal 37 are disposed in the first region S1; the second blue-light chip 35 and the second package colloidal 38 are disposed in the second region S2; the green-light phosphor GP is mixed into the second package colloidal 38; the third blue-light chip 36 and the fourth package colloidal 39 are disposed in the third region S3; the red-light phosphor RP is mixed into the fourth package colloidal 39.

The first blue-light chip 34 has a monochromatic emission spectrum of a first blue-light band; the second blue-light chip 35 has a monochromatic emission spectrum of a second blue-light band; the third blue-light chip 36 has a monochromatic emission spectrum of a third blue-light band. The first package colloidal 37 is used to cover and package the first blue-light chip 34; the second package colloidal 38 is used to cover and package the second blue-light chip 35; the fourth package colloidal 39 is used to cover and package the third blue-light chip 36.

It should be noticed that the green-light phosphor GP mixed in the second package colloidal 38 can completely convert the monochromatic emission spectrum of the second blue-light band emitted from the second blue-light chip 35 into a monochromatic emission spectrum of a green-light band. In other words, the spectrum of the lights emitted from the second package colloidal 38 will focus on the green-light band without the blue lights emitted from the second blue-light chip 35. In a preferred embodiment, in order to reach the complete conversion of the spectrum, the concentration of the green-light phosphor GP can be adjusted to a suitable range, or the composition of the green-light phosphor GP can be suitably adjusted.

In addition, the red-light phosphor RP mixed in the fourth package colloidal 39 can completely convert the monochromatic emission spectrum of the third blue-light band emitted from the third blue-light chip 36 into a monochromatic emission spectrum of a red-light band. In other words, the spectrum of the lights emitted from the fourth package colloidal 39 will focus on the red-light band without the blue lights emitted from the third blue-light chip 36. In a preferred embodiment, in order to reach the complete conversion of the spectrum, the concentration of the red-light phosphor RP can be adjusted to a suitable range, or the composition of the red-light phosphor RP can be suitably adjusted.

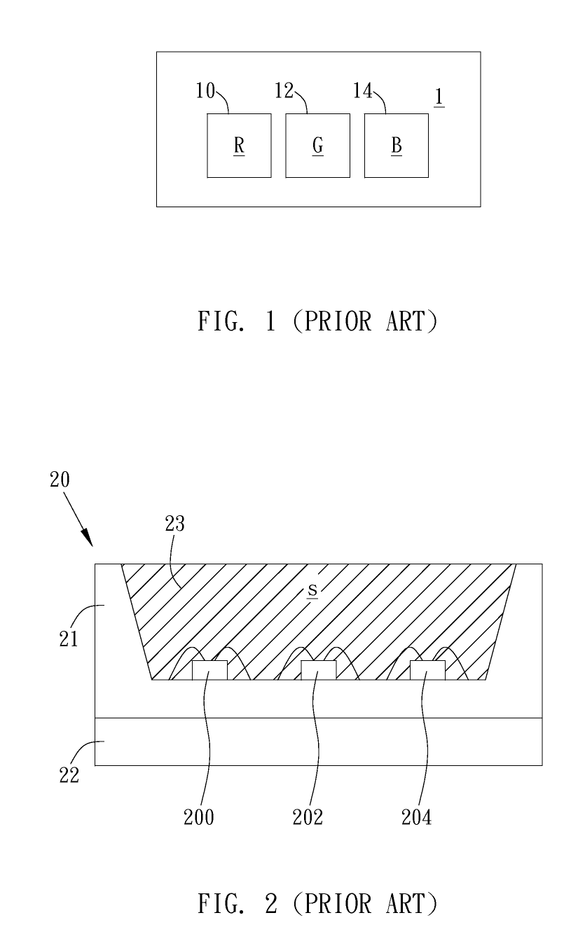

TABLE 1

| Types of | | | | | | | | |
|---|---|---|---|---|---|---|---|---|
| LED | Driving current (mA) | | | CIE | | | | |
| apparatus | B | G | R | x | y | lm | W | lm/W |
| FIG. 2 | 30 | 70 | 80 | 0.258 | 0.231 | 21.5 | 0.5 | 43.2 |
| FIG. 3 | 30 | 40 | 40 | 0.259 | 0.230 | 21.4 | 0.32 | 67.8 |
| FIG. 4 | 30 | 45 | 40 | 0.260 | 0.231 | 21.4 | 0.31 | 69.9 |

The LED apparatus 3 shown in FIG. 3 uses the second blue-light chip 35 and the green-light phosphor GP in the second region S2 to replace the conventional green-light chip, and the LED apparatus 3 uses the third blue-light chip 36 and the red-light phosphor RP to replace the conventional red-light chip. Please refer to Table 1. Table 1 shows the experimental data of the overall efficiency of the LED apparatus in FIG. 2, FIG. 3, and FIG. 4. As shown in Table 1, it is proved by experiments that the overall efficiency value (lm/W) of the LED apparatus 3 in FIG. 3 is 67.8, but the overall efficiency value (lm/W) of the conventional LED apparatus 20 in FIG. 2 is only 43.2. That is to say, the overall efficiency of the LED apparatus 3 in FIG. 3 is 57% higher than that of the conventional LED apparatus 20 in FIG. 2. Wherein, the so-called “overall efficiency” means the output flux/the input power, and its unit is lm/W. The overall efficiency is used to compare the white-light efficiencies of the white lights formed by the three RGB light sources, that is to say, overall efficiency is used to compare the intensity of the white lights formed by the three RGB light sources.

TABLE 2

| | Types of LED apparatus | | | | | | |
|---|---|---|---|---|---|---|---|
| | | | | | LED apparatus using | | |
| | LED apparatus using | | | | blue-light chip and | | |
| | red-light chip | | | | red-light phosphor | | |
| Relative | 100.0 | 86.8 | 71.0 | 57.7 | 100.0 | 87.8 | 75.4 |
| intensity (%) | | | | | | | |
| Tj (□) | 29.7 | 51.6 | 75.1 | 102.4 | 33.1 | 78.3 | 114.0 |
| Thermal | N/A | −0.60 | −0.64 | −0.58 | N/A | −0.27 | −0.3 |
| stability (%/□) | | | | | | | |

Please refer to Table 2. Table 2 shows the experimental data of the thermal stability of the conventional LED apparatus 20 using the red-light chip 200 in FIG. 2 and the LED apparatus 3 using the blue-light chip 36 and the red-light phosphor RP in FIG. 3. As shown in Table 2, it is proved by experiments that the amplitude of the relative intensity of the conventional LED apparatus 20 using the red-light chip 200 in FIG. 2 changing with temperature, namely the thermal stability, is about −0.6%/□; the amplitude of the relative intensity of the LED apparatus 3 using the blue-light chip 36 and the red-light phosphor RP in FIG. 3 changing with temperature, namely the thermal stability, is about −0.3%/° C. That is to say, the thermal stability of the LED apparatus 3 using the blue-light chip 36 and the red-light phosphor RP in FIG. 3 is better than that of the conventional LED apparatus 20 using the red-light chip 200 in FIG. 2. This is because the LED apparatus 3 uses the blue-light chip 36 and the red-light phosphor RP to replace the conventional red-light chip in the third region S3, the thermal stability of the LED apparatus 3 is 50% better than that of the conventional red-light chip. Wherein, the so-called “thermal stability” means the relative intensity decreasing amount/the increasing environment temperature, and its unit is %/° C. For the same increasing environment temperature, if the relative intensity decreasing amount is less, the absolute value of the thermal stability will be also less; that is to say, the amplitude of the relative intensity has less change with temperature, therefore, it means better thermal stability, and vice versa.

In this embodiment, in the LED apparatus 3 of the CS-LCD, the first blue-light chip 34, the second blue-light chip 35, and the third blue-light chip 36 disposed in the first region S1, the second region S2, and the third region S3 respectively emit the monochromatic emission spectra of the first blue-light band, the second blue-light band, and the third blue-light band in order at a specific time. Wherein, the monochromatic emission spectrum of the second blue-light band emitted from the second blue-light chip 35 will be completely converted into the monochromatic emission spectrum of a green-light band by the green-light phosphor GP mixed in the second package colloidal 38; the monochromatic emission spectrum of the third blue-light band emitted from the third blue-light chip 36 will be completely converted into the monochromatic emission spectrum of a red-light band by the red-light phosphor RP mixed in the fourth package colloidal 39. The color sequence switching rate among the first blue-light band, the green-light band, and the red-light band is faster than the perceiving frequency (60 Hz) of human eyes, human brain will superpose the screen effects to feel the full-color screen due to the vision persistence effect.

In practical applications, because silicate, oxynitride, lutetium aluminum oxide, and calcium scandium oxide can be used to completely convert the monochromatic emission spectrum of the second blue-light band of the second blue-light chip 35 into the monochromatic emission spectrum of the green-light band, the green-light phosphor GP mixed in the second package colloidal 38 can be silicate, oxynitride, lutetium aluminum oxide, or calcium scandium oxide, but not limited to these cases.

In an embodiment, the silicate is selected as the green-light phosphor GP mixed in the second package colloidal 38. If the weight ratio between the green-light phosphor GP (silicate) and the second package colloidal 38 is less than 80%, the green-light phosphor GP (silicate) will fail to completely convert the monochromatic emission spectrum of the second blue-light band of the second blue-light chip 35 into the monochromatic emission spectrum of the green-light band. That is, the weight ratio between the green-light phosphor GP and the second package colloidal 38 is higher; the efficiency of the converting is higher. However, the higher weight ratio results bigger volume to shield more luminescent area. It reduces the efficiency of the luminescence. In some embodiments, the weight ratio between the green-light phosphor GP and the second package colloidal 38 is over than 160%, the efficiency of the luminescence is too lower to apply to practice. Therefore, it is better that the weight ratio between the green-light phosphor GP (silicate) and the second package colloidal 38 ranges between 80% and 160%. In fact, since (Ca,Sr,Ba)₂SiO₄:Eu can be used to completely convert the monochromatic emission spectrum of the second blue-light band of the second blue-light chip 35 into the monochromatic emission spectrum of the green-light band, the silicate selected as the green-light phosphor GP can include (Ca,Sr,Ba)₂SiO₄:Eu, but not limited to this case.

In another embodiment, the oxynitride is selected as the green-light phosphor GP mixed in the second package colloidal 38. If the weight ratio between the green-light phosphor GP (oxynitride) and the second package colloidal 38 is less than 90%, the green-light phosphor GP (oxynitride) will fail to completely convert the monochromatic emission spectrum of the second blue-light band of the second blue-light chip 35 into the monochromatic emission spectrum of the green-light band. In some embodiments, the weight ratio between the green-light phosphor GP and the second package colloidal 38 is over than 180%, the efficiency of the luminescence is too lower to apply to practice. Therefore, it is better that the weight ratio between the green-light phosphor GP (oxynitride) and the second package colloidal 38 ranges between 90% and 180%. In fact, since β-SiAlON:Eu can be used to completely convert the monochromatic emission spectrum of the second blue-light band of the second blue-light chip 35 into the monochromatic emission spectrum of the green-light band, the oxynitride selected as the green-light phosphor GP can include β-SiAlON:Eu, but not limited to this case.

In another embodiment, the lutetium aluminum oxide is selected as the green-light phosphor GP mixed in the second package colloidal 38. If the weight ratio between the green-light phosphor GP (lutetium aluminum oxide) and the second package colloidal 38 is less than 80%, the green-light phosphor GP (lutetium aluminum oxide) will fail to completely convert the monochromatic emission spectrum of the second blue-light band of the second blue-light chip 35 into the monochromatic emission spectrum of the green-light band. In some embodiments, the weight ratio between the green-light phosphor GP and the second package colloidal 38 is over than 160%, the efficiency of the luminescence is too lower to apply to practice. Therefore, it is better that the weight ratio between the green-light phosphor GP (lutetium aluminum oxide) and the second package colloidal 38 ranges between 80% and 160%. In fact, since Lu₃Al₅O₁₂:Ce can be used to completely convert the monochromatic emission spectrum of the second blue-light band of the second blue-light chip 35 into the monochromatic emission spectrum of the green-light band, the lutetium aluminum oxide selected as the green-light phosphor GP can include Lu₃Al₅O₁₂:Ce, but not limited to this case.

In another embodiment, the calcium scandium is selected as the green-light phosphor GP mixed in the second package colloidal 38. If the weight ratio between the green-light phosphor GP (calcium scandium) and the second package colloidal 38 is less than 90%, the green-light phosphor GP (calcium scandium) will fail to completely convert the monochromatic emission spectrum of the second blue-light band of the second blue-light chip 35 into the monochromatic emission spectrum of the green-light band. In some embodiments, the weight ratio between the green-light phosphor GP and the second package colloidal 38 is over than 180%, the efficiency of the luminescence is too lower to apply to practice. Therefore, it is better that the weight ratio between the green-light phosphor GP (calcium scandium) and the second package colloidal 38 ranges between 90% and 180%. In fact, since CaSc₂O₄:Ce can be used to completely convert the monochromatic emission spectrum of the second blue-light band of the second blue-light chip 35 into the monochromatic emission spectrum of the green-light band, the calcium scandium oxide selected as the green-light phosphor GP can include CaSc₂O₄:Ce, but not limited to this case.

In practical applications, because nitride can be used to completely convert the monochromatic emission spectrum of the third blue-light band emitted from the third blue-light chip 36 into the monochromatic emission spectrum of the red-light band, the red-light phosphor RP mixed in the fourth package colloidal can be nitride, but not limited to this case.

In an embodiment, the nitride is selected as the red-light phosphor RP of the third package colloidal 39. If the weight ratio between the red-light phosphor RP (nitride) and the third package colloidal 39 is less than 24%, the red-light phosphor RP (nitride) will fail to completely convert the monochromatic emission spectrum of the third blue-light band emitted from the third blue-light chip 36 into the monochromatic emission spectrum of the red-light band. That is, the weight ratio between the red-light phosphor RP and the third package colloidal 39 is higher; the efficiency of the converting is higher. However, the higher weight ratio results bigger volume to shield more luminescent area. It reduces the efficiency of the luminescence. In some embodiments, the weight ratio between the red-light phosphor RP and the third package colloidal 39 is over than 120%, the efficiency of the luminescence is too lower to apply to practice. Therefore, it is better that the weight ratio between the red-light phosphor RP (nitride) and the third package colloidal 39 ranges between 24% and 120%. In fact, since (Ca,Sr)AlSiN₃:Eu and (Ca,Sr,Ba)₂Si₅N₈:Eu can be used to completely convert the monochromatic emission spectrum of the third blue-light band emitted from the third blue-light chip 36 into the monochromatic emission spectrum of the red-light band respectively, the nitride selected as the red-light phosphor RP can include (Ca,Sr)AlSiN₃:Eu or (Ca,Sr,Ba)₂Si₅N₈:Eu, but not limited to this case.

Another preferred embodiment of the invention is also a LED apparatus applied in the LCD. In this embodiment, the LCD is a CS-LCD or a direct-type LCD. The LCD includes a liquid crystal panel and a backlight module, and the backlight module is disposed corresponding to the liquid crystal panel. The backlight module includes a frame and a LED light bar, and the LED light bar is disposed in the frame. The LED light bar includes a circuit board and a LED apparatus, and the LED apparatus is disposed on the circuit board. Then, the LED apparatus of the above-mentioned backlight module will be discussed in detail as follows.

Please refer to FIG. 4. FIG. 4 illustrates a cross-sectional view of the LED apparatus in this embodiment. As shown in FIG. 4, the LED apparatus 4 includes a substrate 40, a cup structure 41, a first dividing structure 42, a second dividing structure 43, a first blue-light chip 44, a second blue-light chip 45, a red-light chip 46, a first package colloidal 47, a second package colloidal 48, a third package colloidal 49, and a green-light phosphor GP. The cup structure 41 is disposed on the substrate 40 and encloses a containing space. The first dividing structure 42 and the second dividing structure 43 are disposed in the containing space, and the first dividing structure 42 and the second dividing structure 43 divide the containing space into a first region S1, a second region S2, and a third region S3. Wherein, the first blue-light chip 44 and the first package colloidal 47 are disposed in the first region S1; the second blue-light chip 45 and the second package colloidal 48 are disposed in the second region S2, and the green-light phosphor GP is mixed in the second package colloidal 48; the red-light chip 46 and the third package colloidal 49 is disposed in the third region S3.

Comparing FIG. 3 with FIG. 4, it can be found that the largest difference between the LED apparatus 3 in FIG. 3 and the LED apparatus 4 in FIG. 4 is that the red-light phosphor is not mixed into the third package colloidal 49 disposed in the third region S3 of the LED apparatus 4, and the red-light chip 46, instead of the blue-light chip, is disposed in the third region S3. Therefore, the monochromatic emission spectrum of the red-light band emitted from the red-light chip 46 will be maintained unchanged.

As shown in Table 1, it is proved by experiments that the overall efficiency value (lm/W) of the LED apparatus 4 in FIG. 4 is 69.9, but the overall efficiency value (lm/W) of the conventional LED apparatus 20 in FIG. 2 is only 43.2. That is to say, the overall efficiency of the LED apparatus 4 in FIG. 4 is 62% higher than that of the conventional LED apparatus 20 in FIG. 2. This obvious effect is caused due to the conventional green-light chip in the second region S2 of the LED apparatus 4 is replaced by the second blue-light chip 45 and the green-light phosphor GP.

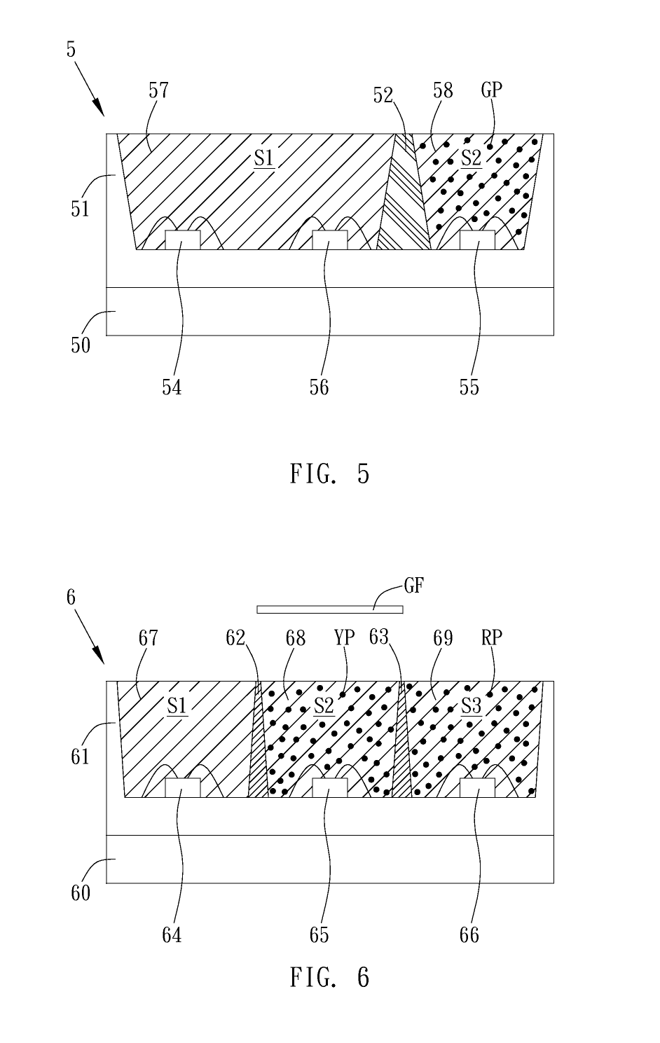

In another preferred embodiment of the invention, as shown in FIG. 5, the LED apparatus 5 includes a substrate 50, a cup structure 51, a dividing structure 52, a first blue-light chip 54, a second blue-light chip 55, a red-light chip 56, a first package colloidal 57, a second package colloidal 58, and a green-light phosphor GP. The cup structure 51 is disposed on the substrate 50 and encloses a containing space. The dividing structure 52 is disposed in the containing space, and the dividing structure 52 divides the containing space into a first region S1 and a second region S2. Wherein, the first blue-light chip 54, the red-light chip 56, and the first package colloidal 57 are disposed in the first region S1; the second blue-light chip 55 and the second package colloidal 58 are disposed in the second region S2; the green-light phosphor GP is mixed in the second package colloidal 58.

Comparing FIG. 4 with FIG. 5, it can be found that the largest difference between the LED apparatus 4 in FIG. 4 and the LED apparatus 5 in FIG. 5 is that the containing space formed by the cup structure 51 of the LED apparatus 5 in FIG. 5 is only divided into the first region S1 and the second region S2, and the first blue-light chip 54 and the red-light chip 56 are disposed in the first region S1, and the red-light phosphor is not mixed into the first package colloidal 57 in the first region S1. That is to say, the blue light and the red light are mixed in the first region S1, but the conventional green-light chip is replaced by the second blue-light chip 55 and the green-light phosphor GP in the second region S2. As shown in Table 1, it is proved by experiments that its overall efficiency can be about 62% higher than the conventional green-light chip.

Similarly, the red-light chip 56 in the above-mentioned embodiment can be replaced by a green-light chip, and a red-light phosphor RP is mixed in the second package colloidal 58. By doing so, the blue light and the green light are mixed in the first region S1, but the conventional red-light chip is replaced by the second blue-light chip 55 and the red-light phosphor RP in the second region S2. As shown in Table 2, it is proved by experiments that its thermal stability can be about 50% higher than the conventional red-light chip.

The LED apparatus of the invention can be also used in a hybrid field sequential color display. When the hybrid field sequential color display cooperates with a color filter, the LED apparatus will correspondingly emit three kinds of light sources including the white light. For example, when the hybrid field sequential color display cooperates with a green color filter, the LED apparatus will emit a white light, a red light, and a blue light; when the hybrid field sequential color display cooperates with a red color filter, the LED apparatus will emit a white light, a green light, and a blue light; when the hybrid field sequential color display cooperates with a blue color filter, the LED apparatus will emit a white light, a red light, and a red light. Next, the above-mentioned three conditions will be described in FIG. 6˜FIG. 8.

Please refer to FIG. 6. FIG. 6 illustrates a cross-sectional view of the LED apparatus cooperating with a green color filter. As shown in FIG. 6, the LED apparatus 6 includes a substrate 60, a cup structure 61, a first dividing structure 62, a second dividing structure 63, a first blue-light chip 64, a second blue-light chip 65, a third blue-light chip 66, a first package colloidal 67, a second package colloidal 68, a third package colloidal 69, a yellow-light phosphor YP, and a red-light phosphor RP.

In this embodiment, the cup structure 61 is disposed on the substrate 60 and encloses a containing space. The first dividing structure 62 and the second dividing structure 63 are disposed in the containing space, and the first dividing structure 62 and the second dividing structure 63 divide the containing space into a first region S1, a second region S2, and a third region S3. Wherein, the first blue-light chip 64 and the first package colloidal 67 are disposed in the first region S1; the second blue-light chip 65 and the second package colloidal 68 are disposed in the second region S2; the yellow-light phosphor YP is mixed into the second package colloidal 68; the third blue-light chip 66 and the third package colloidal 69 are disposed in the third region S3; the red-light phosphor RP is mixed into the third package colloidal 69. In this embodiment, the first region S1 can form a blue light, the second region S2 can form a white light, and the third region S3 can form a red light. A green light can be formed by the white light of the second region S2 cooperating with the green color filter GF. Therefore, the LED apparatus of this embodiment can cooperate with a partial green color filter GF to be applied in the hybrid field sequential color display.

It should be mentioned that the yellow-light phosphor YP mixed in the second package colloidal 68 can be replaced by a yellow-light (YP) and red-light phosphor (RP) or a green-light (GP) and red-light (RP) phosphor; that is to say, if a phosphor can cooperate with the blue-light chip to form a white light, it is suitable to be mixed in the second package colloidal 68. In practical applications, the yellow-light phosphor YP can be silicate, nitride, or yttrium aluminum garnet (YAG), wherein the nitride can include La₃Si₆N₁₁:Ce, but not limited to this; the red-light phosphor RP can be nitride, such as (Ca,Sr)AlSiN₃:Eu or (Ca,Sr,Ba)₂Si₅N₈:Eu, but not limited to this.

The first blue-light chip 64 has a monochromatic emission spectrum of a first blue-light band; the second blue-light chip 65 has a monochromatic emission spectrum of a second blue-light band; the third blue-light chip 66 has a monochromatic emission spectrum of a third blue-light band. The first package colloidal 67 is used to cover and package the first blue-light chip 64; the second package colloidal 68 is used to cover and package the second blue-light chip 65; the third package colloidal 69 is used to cover and package the third blue-light chip 66.

It should be noticed that the yellow-light phosphor YP mixed in the second package colloidal 68 can convert a part of the monochromatic emission spectrum of the second blue-light band of the second blue-light chip 65 into a monochromatic emission spectrum of a yellow-light band, and then mixed with another part of the monochromatic emission spectrum of the second blue-light band to generate a white light. Since the LED apparatus 6 is cooperated with the green color filter GF, the white light emitted from the second package colloidal 68 will pass through the green color filter GF and converted into a green light.

In addition, the red-light phosphor RP mixed in the third package colloidal 69 can also completely convert the monochromatic emission spectrum of the third blue-light band of the third blue-light chip 66 into a monochromatic emission spectrum of a red-light band; that is to say, the spectrum of the light emitted from the third package colloidal 69 will be concentrated in the red-light band, and the blue-light of the monochromatic emission spectrum of the third blue-light chip 66 will not be emitted from the third package colloidal 69. In order to reach the complete conversion of the spectrum, in a preferred embodiment, the concentration of the red-light phosphor RP can be adjusted to a suitable range, or the composition of the red-light phosphor RP can be suitably adjusted. And, the third blue-light chip 66 can be also replaced by a red-light chip to generate a monochromatic emission spectrum of a red-light band.

In this embodiment, in the LED apparatus 6 suitable used in the hybrid field sequential color display, the first blue-light chip 64, the second blue-light chip 65, and the third blue-light chip 66 disposed in the first region S1, the second region S2, and the third region S3 respectively emit the monochromatic emission spectra of the first blue-light band, the second blue-light band, and the third blue-light band in order at a specific time, wherein a part of the monochromatic emission spectrum of the second blue-light band emitted from the second blue-light chip 65 will be converted into the monochromatic emission spectrum of the yellow-light band by the yellow-light phosphor YP (or the yellow-light and red-light phosphor, the green-light and red-light phosphor) mixed in the second package colloidal 68, and then mixed with another part of the monochromatic emission spectrum of the second blue-light band to generate the white light. Then, a part of the white light will pass through the green color filter GF and converted into the monochromatic emission spectrum of a green-light band. And, the monochromatic emission spectrum of the third blue-light band of the third blue-light chip 66 can be completely converted into the monochromatic emission spectrum of the red-light band by the red-light phosphor RP mixed in the third package colloidal 69. The third blue-light chip 66 can be also replaced by a red-light chip to generate a monochromatic emission spectrum of a red-light band. Because the color sequence switching rate among the first blue-light band, the white light, the green-light band, and the red-light band is faster than the perceiving frequency (60 Hz) of human eyes, human brain will superpose the screen effects to feel the full-color screen due to the vision persistence effect, and the color break-up (CBU) phenomenon can be reduced by the generated four-color image to improve the quality of the displayed image.

Above all, it can be concluded in the LED apparatus 6 suitable used in the hybrid field sequential color display, the white-light source is formed by a single blue-light chip cooperated with a yellow-light phosphor (or a yellow-light and red-light phosphor, a green-light and red-light phosphor) and the white-light source will be converted into a green light by a green color filter. It is not necessary to drive the chips at the same time to mix the red light, the blue light, and the green light into the white light. Therefore, lm/W of the LED apparatus 6 can be increased to be 80.8˜86.9, that is to say, the overall efficiency value of the LED apparatus 6 is 23%˜32% higher than that of the LED apparatus 3 shown in FIG. 3. Not only the overall efficiency value is largely increased, the LED apparatus 6 also has advantages of stabler white light, higher productivity, and lower cost, therefore, the competitiveness of the hybrid field sequential color display having the LED apparatus 6 can be effectively enhanced.

It should be mentioned that the LED apparatus 6 suitable used in the hybrid field sequential color display in this embodiment has to cooperate with a color filter to function normally. In this embodiment, the color filter of the hybrid field sequential color display is the green color filter which is a color filter having single color, and the green color filter is not shown on all regions of the color filter, it is only partially shown on the color filter. In other words, the green color filter only corresponds to the white-light region of the LED apparatus 6. Therefore, the LED apparatus 6 having white light can cooperate with the color filter of single color to form the image of blue, green, and red. However, this invention is not limited to this, the color filters having different designed colors can cooperate with the LED apparatus 6 having partition structure to form the image of different color combinations. When the LED apparatus of the invention is used in the CS-LCD, the structures of the LED apparatus 3˜5 shown in FIG. 3˜FIG. 5 will be necessary. Compared to the conventional LED apparatus having different color chips (R/GB or W/R/B, etc) set separately, the LED apparatus using three regions in this embodiment can reduce the size of the LED apparatus, and the number of LED in the limited space can be increased to enhance the lightness of the LED apparatus.

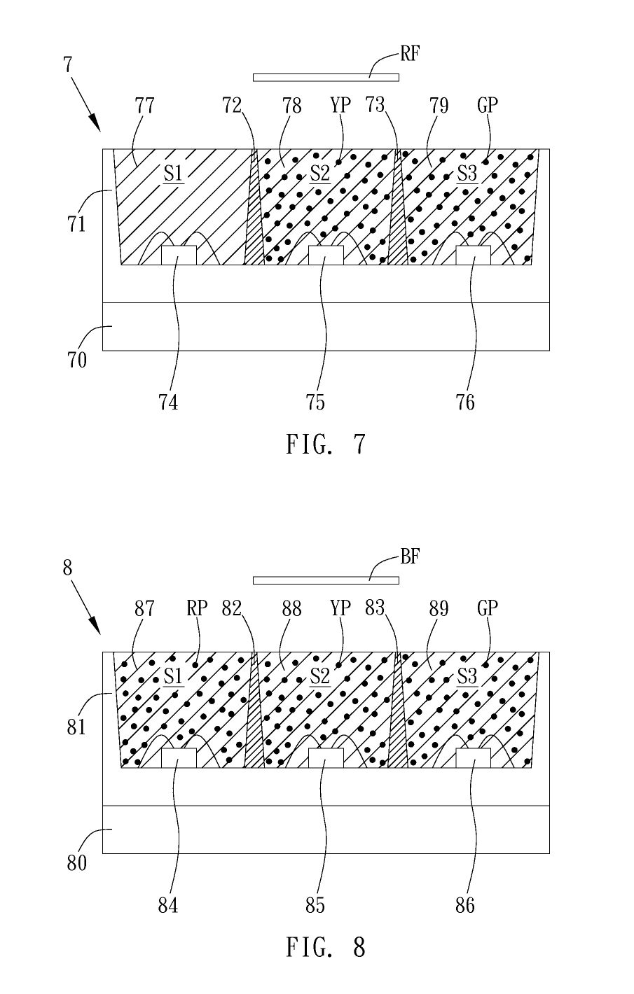

Next, please refer to FIG. 7. FIG. 7 illustrates a cross-sectional view of the LED apparatus cooperating with a red color filter. As shown in FIG. 7, the LED apparatus 7 includes a substrate 70, a cup structure 71, a first dividing structure 72, a second dividing structure 73, a first blue-light chip 74, a second blue-light chip 75, a third blue-light chip 76, a first package colloidal 77, a second package colloidal 78, a third package colloidal 79, a yellow-light phosphor YP, and a green-light phosphor GP.

In this embodiment, the cup structure 71 is disposed on the substrate 70 and encloses a containing space. The first dividing structure 72 and the second dividing structure 73 are disposed in the containing space, and the first dividing structure 72 and the second dividing structure 73 divide the containing space into a first region S1, a second region S2, and a third region S3. In a preferred embodiment, the first dividing structure 72 and the second dividing structure 73 are thinner than the sidewall of the cup structure 71; therefore, the regions can be closer to obtain better light-mixing effect. Wherein, the first blue-light chip 74 and the first package colloidal 77 are disposed in the first region S1; the second blue-light chip 75 and the second package colloidal 78 are disposed in the second region S2; the yellow-light phosphor YP is mixed into the second package colloidal 78; the third blue-light chip 76 and the third package colloidal 79 are disposed in the third region S3, and the green-light phosphor GP is mixed into the third package colloidal 79. In this embodiment, the first region S1 can form a blue light, the second region S2 can form a white light, and the third region S3 can form a green light. A red light can be formed by the white light of the second region S2 cooperating with the red color filter RF. Therefore, the LED apparatus of this embodiment can cooperate with a partial red color filter RF to be applied in the hybrid field sequential color display. It should be mentioned that the yellow-light phosphor YP mixed in the second package colloidal 78 can be replaced by a yellow-light and red-light phosphor or a green-light and red-light phosphor; that is to say, if a phosphor can cooperate with the blue-light chip to form a white light, it is suitable to be mixed in the second package colloidal 78.

It should be noticed that the yellow-light phosphor YP mixed in the second package colloidal 78 can convert a part of the monochromatic emission spectrum of the second blue-light band of the second blue-light chip 75 into a monochromatic emission spectrum of a yellow-light band, and then mixed with another part of the monochromatic emission spectrum of the second blue-light band to generate a white light. Since the LED apparatus 7 is cooperated with the red color filter RF, the white light emitted from the second package colloidal 78 will pass through the red color filter RF and converted into a red light.

In addition, the green-light phosphor GP mixed in the third package colloidal 79 can also completely convert the monochromatic emission spectrum of the third blue-light band of the third blue-light chip 76 into a monochromatic emission spectrum of a green-light band; that is to say, the spectrum of the light emitted from the third package colloidal 79 will be concentrated in the green-light band, and the blue-light of the monochromatic emission spectrum of the third blue-light chip 76 will not be emitted from the third package colloidal 79. In order to reach the complete conversion of the spectrum, in a preferred embodiment, the concentration of the green-light phosphor GP can be adjusted to a suitable range, or the composition of the green-light phosphor GP can be suitably adjusted.

In fact, the green-light phosphor GP can be silicate, oxynitride, lutetium aluminum oxide, sulfide, or calcium scandium oxide, but not limited to these cases. Wherein, the silicate can include (Ca,Sr,Ba)₂SiO₄:Eu; the oxynitride can include β-SiAlON:Eu; the lutetium aluminum oxide can include Lu₃Al₅O₁₂:Ce; the sulfide can include (Ca,Sr,Ba)Ga₂S₄:Eu; the calcium scandium oxide can include CaSc₂O₄:Ce.

In this embodiment, in the LED apparatus 7 suitable used in the hybrid field sequential color display, the first blue-light chip 74, the second blue-light chip 75, and the third blue-light chip 76 disposed in the first region S1, the second region S2, and the third region S3 respectively emit the monochromatic emission spectra of the first blue-light band, the second blue-light band, and the third blue-light band in order at a specific time, wherein a part of the monochromatic emission spectrum of the second blue-light band emitted from the second blue-light chip 75 will be converted into the monochromatic emission spectrum of the yellow-light band by the yellow-light phosphor YP (or the yellow-light and red-light phosphor, the green-light and red-light phosphor) mixed in the second package colloidal 78, and then mixed with another part of the monochromatic emission spectrum of the second blue-light band to generate the white light. Then, a part of the white light will pass through the red color filter RF and converted into the monochromatic emission spectrum of a red-light band. And, the monochromatic emission spectrum of the third blue-light band of the third blue-light chip 76 can be completely converted into the monochromatic emission spectrum of the green-light band by the green-light phosphor GP mixed in the third package colloidal 79. Because the color sequence switching rate among the first blue-light band, the white light, the red-light band, and the green-light band is faster than the perceiving frequency (60 Hz) of human eyes, human brain will superpose the screen effects to feel the fill-color screen due to the vision persistence effect, and the color break-up (CBU) phenomenon can be reduced by the generated four-color image to improve the quality of the displayed image.

In this embodiment, the color filter of the hybrid field sequential color display is the red color filter which is a color filter having single color, and the red color filter is not shown on all regions of the color filter, it is only partially shown on the color filter. In other words, the red color filter only corresponds to the white-light region of the LED apparatus 7. Therefore, the LED apparatus 7 having white light can cooperate with the color filter of single-color to form the image of blue, green, and red. However, this invention is not limited to this, the color filters having different designed colors can cooperate with the LED apparatus 7 having partition structure to form the image of different color combinations.

Please also refer to FIG. 8. FIG. 8 illustrates a cross-sectional view of the LED apparatus cooperating with a blue color filter. As shown in FIG. 8, the LED apparatus 8 includes a substrate 80, a cup structure 81, a first dividing structure 82, a second dividing structure 83, a first blue-light chip 84, a second blue-light chip 85, a third blue-light chip 86, a first package colloidal 87, a second package colloidal 88, a third package colloidal 89, a yellow-light phosphor YP, and a green-light phosphor GP.

In this embodiment, the cup structure 81 is disposed on the substrate 80 and encloses a containing space. The first dividing structure 82 and the second dividing structure 83 are disposed in the containing space, and the first dividing structure 82 and the second dividing structure 83 divide the containing space into a first region S1, a second region S2, and a third region S3. In a preferred embodiment, the first dividing structure 82 and the second dividing structure 83 are thinner than the sidewall of the cup structure 81; therefore, the regions can be closer to obtain better light-mixing effect. Wherein, the first blue-light chip 84 and the first package colloidal 87 are disposed in the first region S1; the second blue-light chip 85 and the second package colloidal 88 are disposed in the second region S2; the yellow-light phosphor YP is mixed into the second package colloidal 88; the third blue-light chip 86 and the third package colloidal 89 are disposed in the third region S3, and the green-light phosphor GP is mixed into the third package colloidal 89. In this embodiment, the first region S1 can form a red light, the second region S2 can form a white light, and the third region S3 can form a green light. A blue light can be formed by the white light of the second region S2 cooperating with the blue color filter BF. Therefore, the LED apparatus of this embodiment can cooperate with a partial blue color filter BF to be applied in the hybrid field sequential color display. It should be mentioned that the yellow-light phosphor YP mixed in the second package colloidal 88 can be replaced by a yellow-light and red-light phosphor or a green-light and red-light phosphor.

It should be noticed that the yellow-light phosphor YP mixed in the second package colloidal 88 can convert a part of the monochromatic emission spectrum of the second blue-light band of the second blue-light chip 85 into a monochromatic emission spectrum of a yellow-light band, and then mixed with another part of the monochromatic emission spectrum of the second blue-light band to generate a white light. Since the LED apparatus 8 is cooperated with the blue color filter BF, the white light emitted from the second package colloidal 88 will pass through the blue color filter BF and converted into a blue light.

In addition, the red-light phosphor RP mixed in the first package colloidal 87 can also completely convert the monochromatic emission spectrum of the first blue-light band of the first blue-light chip 84 into a monochromatic emission spectrum of a red-light band, and the green-light phosphor GP mixed in the third package colloidal 89 can also completely convert the monochromatic emission spectrum of the third blue-light band of the third blue-light chip 86 into a monochromatic emission spectrum of a green-light band. That is to say, the spectrum of the light emitted from the first package colloidal 87 will be concentrated in the red-light band, and the blue-light of the monochromatic emission spectrum of the first blue-light chip 84 will not be emitted from the first package colloidal 87, and the spectrum of the light emitted from the third package colloidal 89 will be concentrated in the green-light band, and the blue-light of the monochromatic emission spectrum of the third blue-light chip 86 will not be emitted from the third package colloidal 89. In order to reach the complete conversion of the spectrum, in a preferred embodiment, the concentration of the red-light phosphor RP and the green-light phosphor GP can be adjusted to a suitable range, or the composition of the red-light phosphor RP and the green-light phosphor GP can be suitably adjusted. And, the first blue-light chip 84 can be replaced by a red-light chip to generate a monochromatic emission spectrum of a red-light band.

In this embodiment, in the LED apparatus 8 suitable used in the hybrid field sequential color display, the first blue-light chip 84, the second blue-light chip 85, and the third blue-light chip 86 disposed in the first region S1, the second region S2, and the third region S3 respectively emit the monochromatic emission spectra of the first blue-light band, the second blue-light band, and the third blue-light band in order at a specific time, wherein a part of the monochromatic emission spectrum of the second blue-light band emitted from the second blue-light chip 85 will be converted into the monochromatic emission spectrum of the yellow-light band by the yellow-light phosphor YP (or the yellow-light and red-light phosphor, the green-light and red-light phosphor) mixed in the second package colloidal 88, and then mixed with another part of the monochromatic emission spectrum of the second blue-light band to generate the white light. Then, a part of the white light will pass through the blue color filter BF and converted into the monochromatic emission spectrum of a blue-light band. And, the monochromatic emission spectrum of the first blue-light band of the first blue-light chip 84 can be completely converted into the monochromatic emission spectrum of the red-light band by the red-light phosphor RP mixed in the first package colloidal 87; the monochromatic emission spectrum of the third blue-light band of the third blue-light chip 86 can be completely converted into the monochromatic emission spectrum of the green-light band by the green-light phosphor GP mixed in the third package colloidal 89. And, the first blue-light chip 84 can be replaced by a red-light chip to generate a monochromatic emission spectrum of a red-light band. Because the color sequence switching rate among the red-light band, the blue-light band, and the green-light band is faster than the perceiving frequency (60 Hz) of human eyes, human brain will superpose the screen effects to feel the full-color screen due to the vision persistence effect, and the color break-up (CBU) phenomenon can be reduced by the generated four-color image to improve the quality of the displayed image.

In this embodiment, the color filter of the hybrid field sequential color display is the blue color filter which is a color filter having single color, and the blue color filter is not shown on all regions of the color filter, it is only partially shown on the color filter. In other words, the blue color filter only corresponds to the white-light region of the LED apparatus 8. Therefore, the LED apparatus 8 having white light can cooperate with the color filter of single-color to form the image of blue, green, and red. However, this invention is not limited to this, the color filters having different designed colors can cooperate with the LED apparatus 8 having partition structure to form the image of different color combinations.

It should be mentioned that although the white light is formed by the middle second region S2 in LED apparatus 6-8 shown in FIG. 6˜FIG. 8, in practical applications, the white light can be also formed by the first region S1 or the third region S3, not limited to this case.

Compared to the prior arts, the LED apparatus in the LCD of the invention uses the blue-light chip and the phosphor to form the green-light monochromatic light source or red-light monochromatic light source to effectively reduce the characteristic differences among the three different color light chips in the conventional LED apparatus. The green-light monochromatic light source formed by the blue-light chip and the phosphor has much higher efficiency than the conventional green-light chip, and the red-light monochromatic light source formed by the blue-light chip and the phosphor has better thermal stability than the conventional red-light chip, therefore, the overall efficiency of the LED apparatus in the invention is obviously better than that of the conventional LED apparatus having three different color light chips. In addition, the invention also discloses the LED apparatus suitable used in the hybrid field sequential color display, it uses a single blue-light chip cooperated with a phosphor to form a white-light source, and cooperates with a red color filter, a blue color filter, or a green color filter to convert a part of the white light into a red light, a blue light, or a green light, it is not necessary to drive chip chips at the same time to mix the red light, the blue light, and the green light into the white light, therefore, the efficiency of the LED apparatus can be largely increased, and the color break-up (CBU) phenomenon can be reduced by the generated four-color image to improve the quality of the displayed image. Moreover, the LED apparatus of the invention also has advantages of stabler white light, higher productivity, and lower cost, so that the competitiveness of the hybrid field sequential color display having the LED apparatus can be effectively enhanced.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A LED apparatus, comprising:
a substrate;
a cup structure, disposed on the substrate and enclosing a containing space; and
a dividing structure, disposed in the containing space and dividing the containing space into a first region and a second region, and the first region comprising:
a first blue-light chip having a monochromatic emission spectrum of a first blue-light band; and
a first package colloidal covering and packaging the first blue-light chip; and
the second region comprising:
a second blue-light chip having a monochromatic emission spectrum of a second blue-light band; and
a second package colloidal covering and packaging the second blue-light chip, the second package colloidal comprising a green-light phosphor completely converting the monochromatic emission spectrum of the second blue-light band of the second blue-light chip into a monochromatic emission spectrum of a green-light band;
wherein the green-light phosphor is selected from one of silicate, oxynitride, lutetium aluminum oxide, and calcium scandium oxide.

2. The LED apparatus of claim 1, wherein the silicate is selected as the green-light phosphor, and the weight ratio between the green-light phosphor and the second package colloidal ranges between 80% and 160%.

3. The LED apparatus of claim 1, wherein the silicate comprises (Ca,Sr,Ba)₂SiO₄:Eu.

4. The LED apparatus of claim 1, wherein the oxynitride is selected as the green-light phosphor, and the weight ratio between the green-light phosphor and the second package colloidal ranges between 90% and 180%.

5. The LED apparatus of claim 1, wherein the oxynitride comprises β-SiAlON:Eu.

6. The LED apparatus of claim 1, wherein the lutetium aluminum oxide is selected as the green-light phosphor, and the weight ratio between the green-light phosphor and the second package colloidal ranges between 80% and 160%.

7. The LED apparatus of claim 1, wherein the lutetium aluminum oxide comprises Lu₃Al₅O₁₂:Ce.

8. The LED apparatus of claim 1, wherein the calcium scandium oxide is selected as the green-light phosphor, and the weight ratio between the green-light phosphor and the second package colloidal ranges between 90% and 180%.

9. The LED apparatus of claim 1, wherein the calcium scandium oxide comprises CaSc₂O₄:Ce.

10. The LED apparatus of claim 1, wherein a first red-light chip is further disposed in the first region, the first red-light chip has a monochromatic emission spectrum of a first red-light band, and the first package colloidal covers and packages the first blue-light chip and the first red-light chip.

11. The LED apparatus of claim 1, wherein the dividing structure further divides the containing space to form a third region.

12. The LED apparatus of claim 11, further comprising a second red-light chip and a third package colloidal, wherein the second red-light chip and the third package colloidal are disposed in the third region, the second red-light chip has a monochromatic emission spectrum of a second red-light band, and the third package colloidal covers and packages the second red-light chip.

13. The LED apparatus of claim 11, further comprising a third blue-light chip and a fourth package colloidal, wherein the third blue-light chip and the fourth package colloidal are disposed in the third region, the third blue-light chip has a monochromatic emission spectrum of a third blue-light band, and the fourth package colloidal covers and packages the third blue-light chip, a red-light phosphor is mixed in the fourth package colloidal, the red-light phosphor completely converts the monochromatic emission spectrum of the third blue-light band into a monochromatic emission spectrum of a red-light band; wherein nitride is selected as the red-light phosphor.

14. The LED apparatus of claim 13, wherein the weight ratio between the red-light phosphor and the third package colloidal ranges between 24% and 120%.

15. The LED apparatus of claim 13, wherein the nitride comprises (Ca,Sr)AlSiN₃:Eu or (Ca,Sr,Ba)₂Si₅N₈:Eu.

16. A LED apparatus, comprising:
a substrate;
a cup structure, disposed on the substrate and enclosing a containing space; and
a dividing structure, disposed in the containing space and dividing the containing space into a first region and a second region, and the first region comprising:
a first blue-light chip having a monochromatic emission spectrum of a first blue-light band; and
a first package colloidal covering and packaging the first blue-light chip; and
the second region comprising:
a second blue-light chip having a monochromatic emission spectrum of a second blue-light band; and
a second package colloidal covering and packaging the second blue-light chip, the second package colloidal comprising a phosphor converting the monochromatic emission spectrum of the second blue-light band of the second blue-light chip into a white-light emission spectrum.

17. The LED apparatus of claim 16, wherein the dividing structure further divides the containing space to form a third region, the third region comprising:
a third blue-light chip having a monochromatic emission spectrum of a third blue-light band;
a third package colloidal covering and packaging the third blue-light chip; and
a red-light or green-light phosphor mixed in the third package colloidal, the red-light phosphor completely converting the monochromatic emission spectrum of the third blue-light band into a monochromatic emission spectrum of a red-light band or the green-light phosphor completely converting the monochromatic emission spectrum of the third blue-light band into a monochromatic emission spectrum of a green-light band.

18. The LED apparatus of claim 16, wherein the dividing structure further divides the containing space to form a third region, the third region comprising:
a third blue-light chip having a monochromatic emission spectrum of a third blue-light band;
a third package colloidal covering and packaging the third blue-light chip;
a red-light phosphor mixed in the third package colloidal, the red-light phosphor completely converting the monochromatic emission spectrum of the third blue-light band into a monochromatic emission spectrum of a red-light band; and
a green-light phosphor mixed in the first package colloidal, the green-light phosphor completely converting the monochromatic emission spectrum of the first blue-light band into a monochromatic emission spectrum of a green-light band.

19. The LED apparatus of claim 16, wherein the phosphor is selected from one of a yellow-light phosphor, a yellow-light and red-light phosphor, and a green-light and red-light phosphor.

20. A field sequential display, comprising:
a display module having a color filter of single color; and
a back-light module having a plurality of LED apparatuses, wherein the LED apparatus comprises:
a substrate;
a cup structure, disposed on the substrate and enclosing a containing space; and
a dividing structure, disposed in the containing space and dividing the containing space into a plurality of regions, a first region of the plurality of regions forming a white light, and the first region corresponding to the color filter of single color.

21. The field sequential display of claim 20, wherein the color partially disposes on the color filter of single color.

22. The field sequential display of claim 20, wherein the color filter of single color is a green color filter, and a second region and a third region of the plurality of regions not corresponding to the green color filter form a blue light and a red light respectively.

23. The field sequential display of claim 20, wherein the color filter of single color light is a red color filter, and a second region and a third region of the plurality of regions not corresponding to the red color filter form a blue light and a green light respectively.

24. The field sequential display of claim 20, wherein the color filter of single color light is a blue color filter, and a second region and a third region of the plurality of regions not corresponding to the blue color filter form a red light and a green light respectively.
